(19) United States
(12) Patent Application Publication
(10) Pub. No.: US 2026/0068562 A1
(43) Pub. Date: Mar. 5, 2026

(54) METAL-BASED PROTECTION OF SILICON-CONTAINING EDGE REGION

(71) Applicant: Tokyo Electron Limited, Tokyo (JP)

(72) Inventors: Scott Lefevre, Albany, NY (US); Joshua Baillargeon, Albany, NY (US)

(21) Appl. No.: 18/819,963

(22) Filed: Aug. 29, 2024

(51) Int. Cl. H01L 21/322; H01L 21/308

(52) U.S. Cl. CPC H01L 21/322

(57) ABSTRACT

A method of protecting an edge region of a substrate includes receiving a substrate into a processing chamber. The substrate includes an exposed silicon-containing edge region (e.g., a bevel region of a wafer substrate) surrounding an interior region underlying a resist layer. The method further includes treating the exposed silicon-containing edge region and the resist layer with a metal halide precursor (such as a tungsten halide) to selectively convert the exposed silicon-containing edge region to a metal-containing protective layer (e.g., including a metal silicide such as tungsten silicide and/or a pure metal such as tungsten). The metal-containing protective layer may be configured to protect the edge region of the substrate during subsequent processing, such as an etch process during which exposed surfaces of the interior region are etched.

### TECHNICAL FIELD

The present invention relates generally to semiconductor processing, and, in particular embodiments, to systems and methods for protecting edge regions of a substrate during subsequent processing.

### BACKGROUND

Semiconductor device fabrication typically involves a series of manufacturing techniques that include formation, patterning, and removal of a number of layers of material on a substrate. To transfer a desired pattern to the substrate, a resist material (e.g., photoresist) may be deposited or grown on the substrate and then patterned using a lithography process to form an etch mask that protects regions of the substrate during a subsequent etching process. Wet or dry etching processes may be used, with plasma etching processes being an example of a dry etching process. Etching processes are used in semiconductor processes to etch a wide variety of materials. For example, silicon and silicon-containing materials are often the target of etching processes. The etching of silicon and silicon-containing materials is important for semiconductor processes at many different stages during semiconductor device fabrication, such as during through-silicon via (TSV) formation, plasma dicing, NAND formation (e.g., 3D-NAND), NOR gate formation, deep trench capacitors, and others.

After the resist material is formed on the substrate, the edge region of the substrate is often exposed, such as after the resist material is removed from the edge region using an edge bead removal process. The edge region may be exposed for various reasons, such as to reduce contamination during handling of the substrate, improve uniformity of the resist layer, etc. For example, the substrate (e.g., a wafer substrate) may need to be handled or stored after the resist layer is formed, such as in a front opening unified pod (FOUP). When the substrate is in the FOUP, the edge region of the substrate is in close physical contact with surfaces of the FOUP, which may lead contamination from the resist material being rubbed off. Regarding uniformity, the resist material may have much different profile in the edge region due to the substrate, which may result in undesirable defect formation during the etching process.

During a subsequent etching process that uses the patterned resist material as an etch mask, exposed surfaces of interior regions are exposed to the etchant (i.e., the developed mask pattern). However, the substrate surface in the edge region is also exposed, leaving the surface in the edge region unprotected. The exposed surfaces of the edge region are often the same material as the target material of the etching process (e.g., a silicon-containing material). Moreover, the etching process may be relatively long and the edge region may have a relatively large surface area (e.g., a width on the order of a millimeter). As a result, the edge region may be irregularly etched creating rough surfaces and leading to a multitude of problems, including foreign matter problems. For example, an untenable amount of silicon dust may be generated from the edge region (e.g., during the etch or rubbed off of rough surfaces) that is redeposited in other regions of the substrate, other substrates during transport, etc. Polymer may also accumulate on the rough surfaces in the edge region, which may be difficult or impossible to remove.

Therefore, systems and methods for protecting edge regions of a substrate during etching processes are desirable.

### SUMMARY

In accordance with an embodiment of the invention, a method of protecting an edge region of a substrate includes receiving a substrate into a processing chamber. The substrate includes an exposed silicon-containing edge region surrounding an interior region underlying a resist layer. The method further includes treating the exposed silicon-containing edge region and the resist layer with a metal halide precursor to selectively convert the exposed silicon-containing edge region to a metal-containing protective layer.

In accordance with another embodiment of the invention, a method of protecting an edge region of a substrate during an etching process includes receiving a substrate into a processing chamber where the substrate includes an exposed silicon-containing edge region surrounding an interior region underlying a resist layer, treating the exposed silicon-containing edge region and the resist layer with plasma excited from a tungsten halide precursor gas to selectively convert the exposed silicon-containing edge region to a tungsten-containing protective layer, developing the resist layer to form openings exposing the interior region, and etching the interior region through the openings using the resist layer and the tungsten-containing protective layer as etch masks.

In accordance with still another embodiment of the invention, a system includes a processing chamber, a substrate holder disposed in the processing chamber, a precursor source fluidically coupled to the processing chamber, and at least one controller operatively coupled to the precursor source. The substrate holder is configured to support a substrate including an exposed silicon-containing edge region surrounding an interior region underlying a resist layer. The precursor source is configured to provide a metal halide precursor into the processing chamber. The at least one controller includes one or more processors and at least one non-transitory computer-readable medium storing one or more programs including instructions that, when executed by the one or more processors, cause the system to treat the exposed silicon-containing edge region and the resist layer with the metal halide precursor to selectively convert the exposed silicon-containing edge region to a metal-containing protective layer.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 schematically illustrates an example process that includes a conversion step during which an exposed silicon-containing edge region of a substrate is exposed to a metal halide precursor to convert the edge region of the substrate to a metal-containing protective layer in accordance with embodiments of the invention;

FIGS. 2A-2C schematically illustrate an example etching process that includes a conversion step to convert an edge region of a substrate to a metal-containing protective layer where FIG. 2A shows an edge bead removal step, FIG. 2B shows a conversion step and a development step, and FIG. 2C shows an etch step and a metal removal step in accordance with embodiments of the invention;

FIG. 3 schematically illustrates an example process that includes a conversion step to convert exposed silicon-containing material in both an edge region and exposed interior regions of a substrate to metal-containing protective material in accordance with embodiments of the invention;

FIG. 4 schematically illustrates an example etching process that includes an etch step after a conversion step to convert exposed silicon-containing material in both an edge region and exposed interior regions of a substrate to metal-containing protective material in accordance with embodiments of the invention;

FIG. 5 schematically illustrates another example etching process that includes a conversion step to convert exposed silicon-containing material in both an edge region and exposed interior regions of a substrate to metal-containing protective material in accordance with embodiments of the invention;

FIG. 6 schematically illustrates an example etching process that includes a conversion step to convert an edge region of a substrate to a metal-containing protective layer and an oxidation step to convert the metal-containing protective layer to a metal oxide-containing protective layer in accordance with embodiments of the invention;

FIG. 7 schematically illustrates an example system usable to perform methods and processes that include a conversion step during which an exposed silicon-containing edge region of a substrate is exposed to a metal halide precursor to convert the edge region to a metal-containing protective layer in accordance with embodiments of the invention; and

FIG. 8 illustrates a flowchart of a method of protecting an edge region of a substrate that may be implemented by processes that include a conversion step during which an exposed silicon-containing edge region of a substrate is exposed to a metal halide precursor to convert the edge region to a metal-containing protective layer in accordance with embodiments of the invention.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope. Unless specified otherwise, the expressions “around”, “approximately”, and “substantially” signify within 10%, and preferably within 5% of the given value or, such as in the case of substantially zero, less than 10% and preferably less than 5% of a comparable quantity.

Exposure of some amount of the edge of a substrate, such as a wafer substrate (e.g., a silicon wafer), may be desirable for a variety of reasons related to processing the substrate. For example, the resist material formed on the edge region of the substrate (e.g., a region with a width on the order of a millimeter, referred to as a bevel in some contexts) may be removed in a process sometimes referred to as an edge bead removal process. During a subsequent etch using the patterned resist material as an etch mask, the exposed edge region may be etched, creating undesirable large recesses and rough surfaces (e.g., nanostructured surfaces, such as black silicon that may lead to the undesirable introduction of foreign matter, such as silicon dust, into the fabrication process). Although this may be problematic for any type of etching process, the detrimental effects may be especially pronounced when the etching process is lengthy, such as through-silicon via (TSV) etches, plasma dicing etches, and others.

Conventional solutions include integration changes that are frequently infeasible or uneconomical as well as additional hardware or films to protect the exposed edge region of the substrate. One particular solution that has been conventionally employed is the use of a bevel cover ring. However, the inclusion of an additional physical object in the edge region of the substrate physically distorts nearby plasma during plasma etching processes creating plasma deformations that undesirably hurt uniformity across the entire substrate and decrease yield near the substrate edges. Protective films also have the drawback of introducing defectivity into the fabrication process and require additional hardware that can undesirably increase cost and complexity (as well as potentially using technologies that are not widely available).

In accordance with embodiments herein described, the invention proposes at method of protecting an exposed silicon-containing edge region of a substrate, such as a wafer bevel, by selectively converting the silicon-containing edge region to a metal-containing protective layer. A resist layer covers interior region of the substrate, but leaves the edge region exposed (e.g., after an edge bead removal process). The silicon-containing edge region is treated with a metal halide precursor (e.g., a tungsten halide precursor) that reacts with the silicon-containing material of the edge region and incorporates the metal into the edge region to form the protective layer. The metal halide precursor may be delivered to the edge region in the gas phase, plasma phase, or a combination thereof. Additional reaction energy may also be provided during the treatment by heating the substrate (e.g., using radiative heating techniques and/or through a substrate support).

In various embodiments, the method may be part of an etching process, such as by developing the resist layer to form openings exposing the interior region (i.e., a patterned resist layer) after the protective layer is formed and then etching the interior region through the openings using the resist layer and the protective layer as etch masks. That is, the metal (e.g., tungsten) residing near the surface of the edge region increases the etch resistance of the edge region allowing the silicon-containing material of the exposed interior surfaces to be etched while etching of the edge region is reduced or eliminated. In some embodiments, the metal-containing protective layer may be selectively chemically removed (e.g., without direct plasma) after the interior region is interior region is etched.

The metal-containing protective material may also be used to protect interior regions during an etching process. For example, a first resist layer may be patterned (e.g., exposed and developed) to form a first set of openings before the metal halide treatment. During the treatment, protective surfaces may be formed in the first set of openings in addition to the protective layer of the edge region. A second resist layer may then be formed and patterned to form a second set of openings through which the interior region is etched. More than one resist layer may also be used for other reasons. For example, a first resist layer may be used to form the protective layer, while a second (e.g., more expensive) resist may be used as the etch mask.

The metal, such as tungsten, may be incorporated into the silicon-containing material of the edge region in various ways, which may be influenced by various processing conditions, such as the chemical composition of the metal halide precursor and the silicon-containing edge region, the duration of the treatment, the use and details of plasma and/or heat during the treatment, gas flowrates, chamber pressure, and others. For example, in various embodiments metal silicide regions are formed in the protective layer, and tungsten silicide is formed in some embodiments. In various embodiments, a layer of substantially pure metal (e.g., substantially pure tungsten) is formed in or on the edge region as all or part of the protective layer. Bonds between the metal and elements other than silicon may also be formed as part of the protective layer. For example, metal nitride bonds may be formed in the protective layer (e.g., such as when the silicon-containing material is silicon nitride). Metal oxide bonds may also be formed, such as by treating the edge region with oxygen after the metal halide treatment.

The embodiment systems, methods, and processes described herein may have various advantages over conventional techniques, such as conventional etching processes that do not protect the edge region or that attempt to protect the edge region using films or cover rings. For example, the embodiment methods of protecting the edge region and associated etching processed may advantageously avoid infeasible or costly integration changes. For example, unlike conventional deposited films used for protecting the edge region, the embodiment methods, systems and processes may advantageously avoid additional hardware, such as complex track hardware.

The metal-containing protective layers (e.g., pure metal, such as tungsten, a metal silicide, such as tungsten silicide) formed during the conversion steps described herein may have the advantage of being much more etch resistant that the silicon-containing materials (e.g., silicon, silicon nitride, etc.). Moreover, this increased selectivity to etching processes may be chemical selectivity, resulting in a large increase in etch resistance provided by thin protective layers that are formed during short (e.g., non-damaging) conversion steps. Furthermore, chemical modification of the silicon-containing material (e.g., using plasma) can provide benefits such as direct control over the amount and type of modification, even allowing selective modifications in other parts of the interior of a substrate when resist patterning is done in stages.

The proposed method of converting an exposed silicon-containing edge region to a metal-containing protective layer may also have the advantage of providing protection to the edge region without a physical object in the etch chamber (e.g., a cover ring). This may advantageously improve etch uniformity and yield, such as by reducing plasma distortion near the edge region. For example, improved uniformity and yield near the edge region may be particularly desirable as more of the areas near the edge region are utilized with scaling.

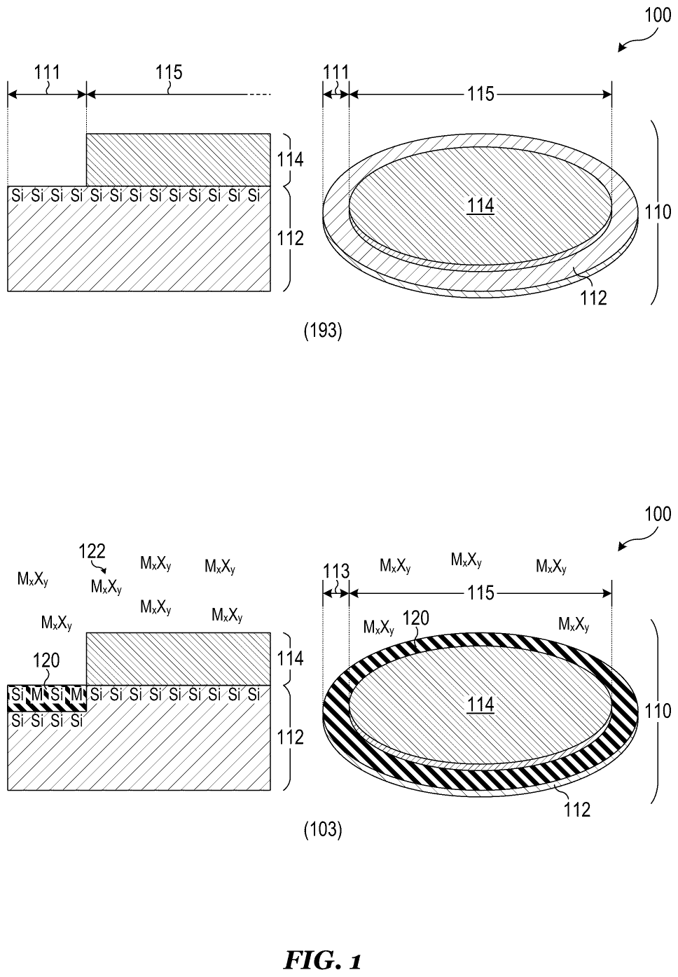

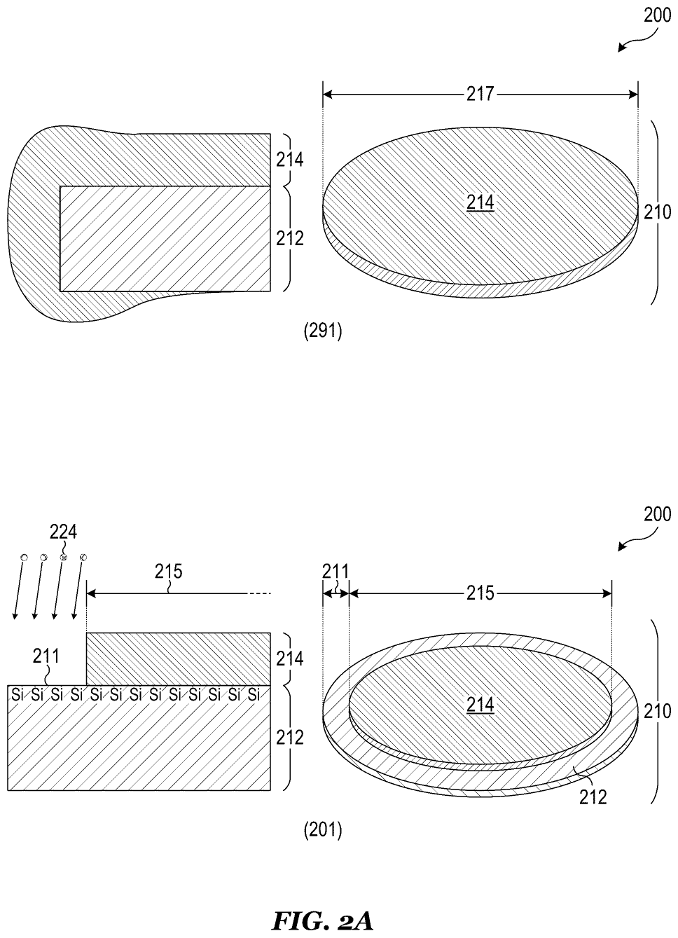

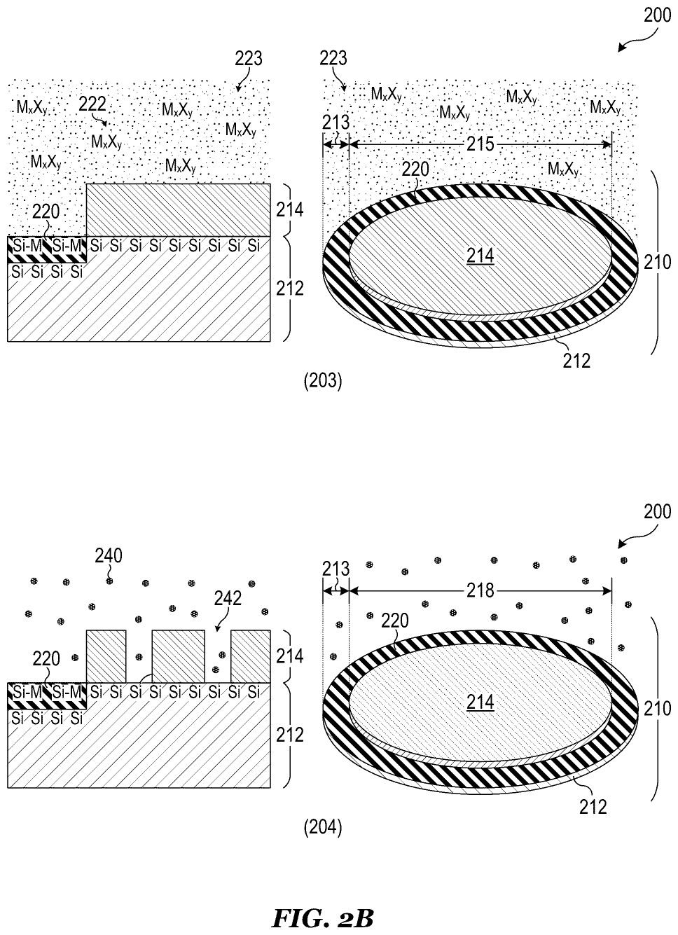

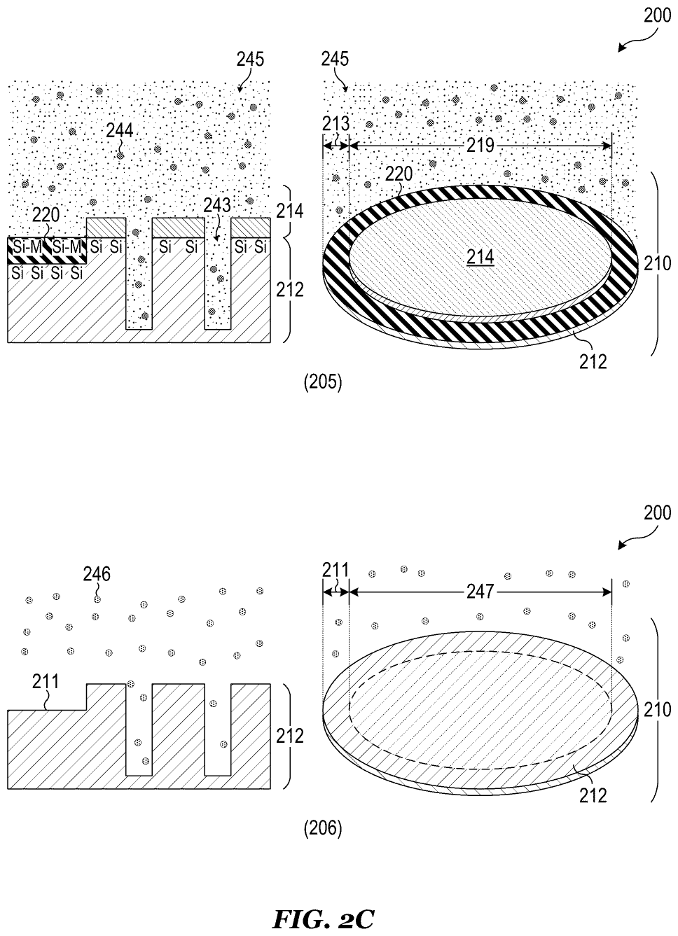

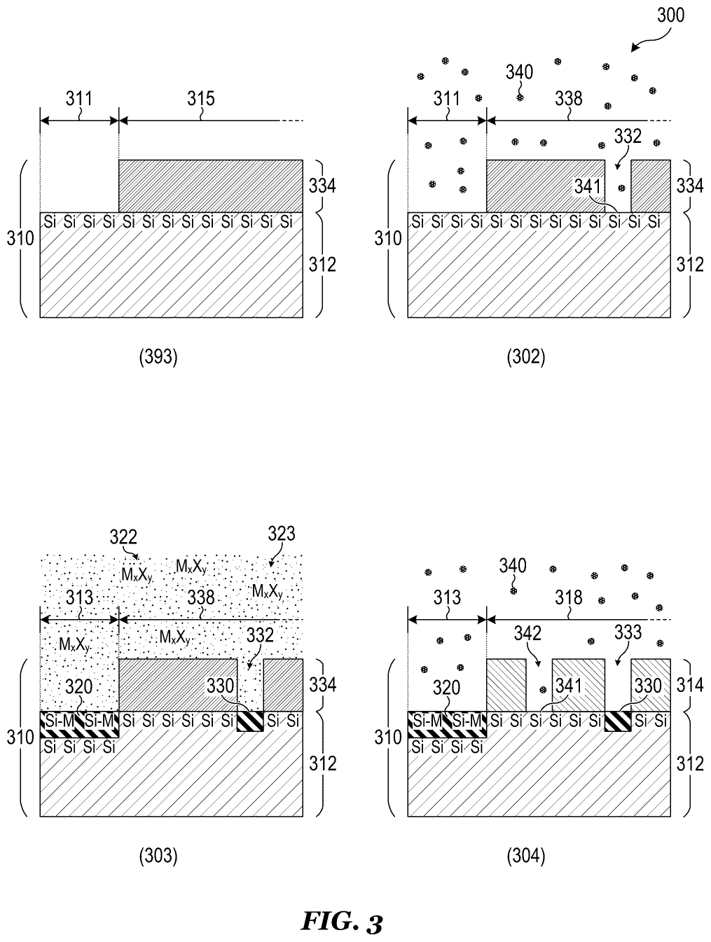

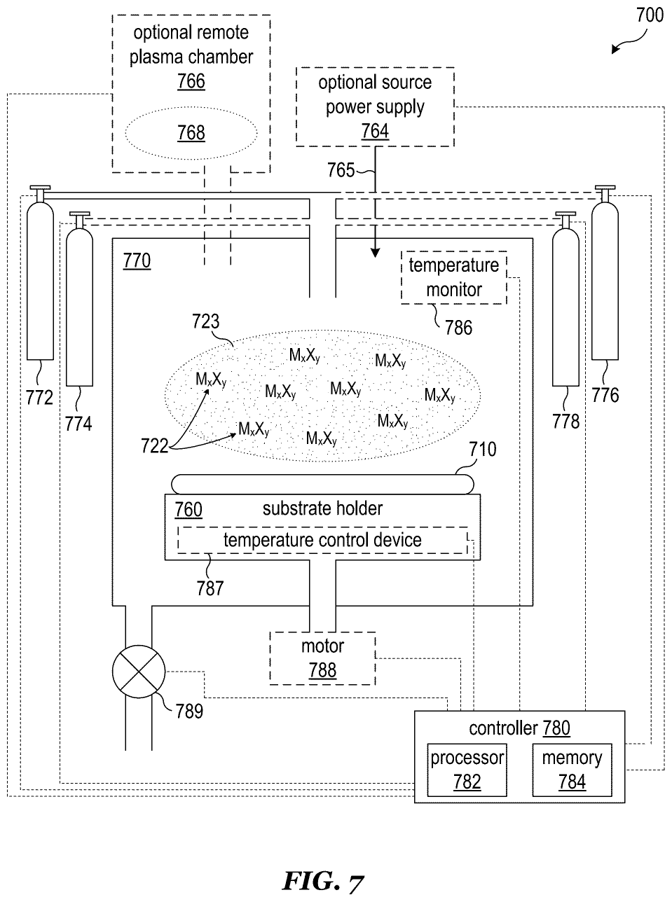

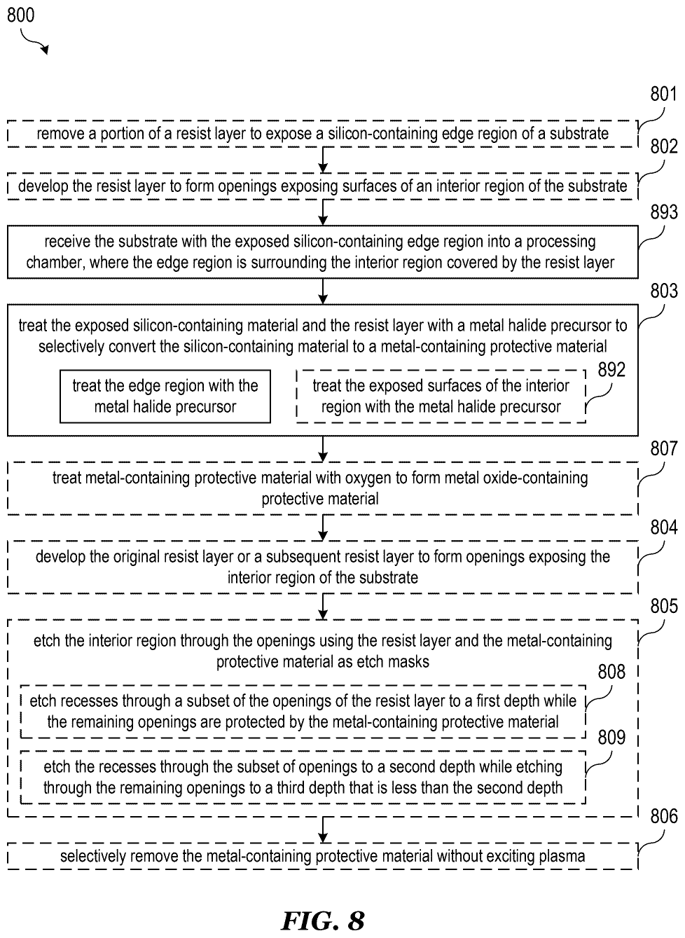

Embodiments provided below describe various systems and methods for protecting edge regions of a substrate during subsequent processing, and in particular, to systems and methods for protecting edge regions of a substrate that include a conversion step during which an exposed silicon-containing edge region of a substrate is exposed to a metal halide precursor to convert the edge region to a metal-containing protective layer. The following description describes the embodiments. FIG. 1 is used to describe an example process including a conversion step. Another example process with a conversion step that includes an edge bead removal step and an etch step is described using FIGS. 2A-2C. Four more example processes that include a conversion step are described using FIGS. 3-6. An example system usable for performing methods and processes that includes a conversion step is described using FIG. 7 while FIG. 8 is used to describe a method of protecting an edge region of a substrate.

FIG. 1 schematically illustrates an example process that includes a conversion step during which an exposed silicon-containing edge region of a substrate is exposed to a metal halide precursor to convert the edge region of the substrate to a metal-containing protective layer in accordance with embodiments of the invention.

Referring to FIG. 1, a process 100 includes a conversion step 103 that is performed on a substrate 110 in an initial state 193. The process 100 may be a part of a larger process (e.g., including additional steps before and/or after the conversion step 103), one specific example of which may be the etching process of FIG. 2. In the initial state 193, the substrate 110 includes a resist layer 114 overlying a silicon-containing material 112 resulting in an exposed edge region 111 and a covered interior region 115. For example, the resist layer 114 may cover the entire substrate when formed and then a portion may be removed (e.g., during an edge bead removal process) or the resist layer 114 may be formed to leave the edge region of the substrate 110 exposed.

In the initial state 193, the substrate 110 may be at any stage of a semiconductor device fabrication process. For example, the substrate 110 (e.g., the silicon-containing material 112) may include various layer, structures, and devices, whether completed or partially incomplete. Additionally, in the initial state 193, the resist layer 114 may be patterned or unpatterned and may be used to protect desired portions of the covered interior region 115 during subsequent processing, such as an etch process. The resist layer 114 may be any suitable type of resist including photoresists (e.g., sensitive to any part of the electromagnetic spectrum, such as G-line resists, I-line resists, deep ultraviolet (DUV) resists, extreme ultraviolet (EUV) resists, X-ray resists, etc.) as well as electron-beam resists.

The substrate 110 may include other materials than the silicon-containing material 112 and the resist layer 114. For example, the substrate 110 may be any suitable substrate, such as an insulating, conducting, or semiconducting substrate with one or more layers (e.g., layers that include the silicon-containing material 112 and the resist layer 114, among other materials) disposed thereon. For example, the substrate 110 may be a semiconductor wafer, such as a silicon wafer, and include various layers, structures, and devices at any stage of completion (e.g., forming integrated circuits). In various embodiments, the silicon-containing material 112 is pure or doped silicon (which may be amorphous, crystalline, or polycrystalline). In other embodiments, the silicon-containing material 112 includes silicon nitride. In still another embodiments, the silicon-containing material 112 includes silicon germanium (SiGe). Of course, many other suitable materials, semiconductor or otherwise, may be included in the substrate 110 as may be apparent to those of skill in the art.

The exposed silicon-containing edge region of the substrate 110 may be referred to an a bevel region in some contexts, such as when the substrate 110 is a semiconductor wafer that includes or is formed of the silicon-containing material 112. For example, the exposed edge region 111 may be used to transport or store the substrate 110 while avoiding contamination from the resist layer 114 and may be large (e.g., on the order of one or a few millimeters, such as between about 1 mm and about 1.5 mm) relative to other structures that may exist or be formed in the interior region of the substrate 110, whether by subsequent processing using the resist layer 114, a future resist layer, or other means.

During the conversion step 103, the silicon-containing material 112 of the exposed edge region 111 is treated with a metal halide precursor 122 (shown as MₓX_{y}, which may be in the gas phase, plasma phase, or a combination thereof) to convert the silicon-containing material 112 into a metal-containing protective layer 120. The resist layer 114 protects the covered interior region 115 (e.g., all of interior region, or only some of the interior region, such as when the resist layer 114 is patterned, which is discussed in further detail in reference to FIGS. 3-5). The metal-containing protective layer 120 covers the exposed edge region 111 and forms a protected edge region 113 (i.e., protected from a subsequent process, such as an etch process).

The metal halide precursor 122 may be in the gas phase, the plasma phase, or a combination thereof. In various embodiments, the metal halide precursor 122 includes metal halide species that are formed as part of a metal halide plasma excited from a metal halide precursor gas. In some embodiments, the metal halide precursor 122 is entirely in the gas phase (such as when the conversion step 103 is performed without plasma and with or without additional substrate heating). Plasma species may also be provided indirectly, such as by sourcing the metal halide precursor 122 from a remote plasma, for example.

The metal in the metal halide precursor 122 (and that subsequently inhabits the metal-containing protective layer 120) may be any suitable metal. In one embodiment, the metal is tungsten (W) and the metal-containing protective layer 120 includes regions of tungsten silicide, pure tungsten, or combinations thereof. In another embodiment, the metal is molybdenum (Mo). Other possible metals include, but are not limited to, refractory metals, such as niobium (Nb), tantalum (Ta), and rhenium (Re), and potentially including other high melting point metals, such as titanium (Ti), vanadium (V), chromium (Cr), zirconium (Zr), ruthenium (Ru), rhodium (Rh), hafnium (Hf), osmium (Os), and iridium (Ir).

The halide component of the metal halide precursor 122 may also vary. For example, the metal halide precursor 122 includes a metal fluoride in various embodiments. Alternatively or additionally, the metal halide precursor 122 is a metal chloride in some embodiments. In one embodiment, the metal halide precursor 122 includes tungsten hexafluoride (WF₆). In another embodiment, the metal halide precursor 122 includes molybdenum hexafluoride (MoF₆). In still another embodiment, the metal halide precursor 122 includes tungsten hexachloride (WCl₆).

The composition of the metal-containing protective layer 120 may depend on various factors, such as the type of metal (or metals) included in the metal halide precursor 122 as well as various processing conditions. In one embodiment, the metal-containing protective layer 120 includes metal-silicon bonds (M-Si). Some examples include tungsten silicide (WSiₓ) and molybdenum silicide (MoSiₓ) in some stoichiometric ratio. In one embodiment, the metal-containing protective layer 120 includes at least a surface layer of pure metal M (e.g., W, Mo, Ti, etc.). Other materials may also be included or formed as part of the metal-containing protective layer 120, such as metal oxides (M-O bonds) and metal nitrides (M-N bonds). On possible configuration leading to metal nitride formation is when the silicon-containing material 112 is or includes silicon nitride. Optionally, the metal-containing protective layer 120 may be treated to form additional types of metal bonds, such as being treated with oxygen (e.g., oxidation) to form metal oxide (discussed later on) or being treated with nitride (e.g., nitridation) to form metal nitride.

FIGS. 2A-2C schematically illustrate an example etching process that includes a conversion step to convert an edge region of a substrate to a metal-containing protective layer where FIG. 2A shows an edge bead removal step, FIG. 2B shows a conversion step and a development step, and FIG. 2C shows an etch step and a metal removal step in accordance with embodiments of the invention. The process of FIGS. 2A-2C may be a specific implementation of or include other processes described herein such as the process of FIG. 1, for example. Similarly labeled elements may be as previously described.

Referring to FIG. 2A, an etching process 200 includes an edge bead removal step 201 that is performed on a substrate 210 in an initial state 291 where a resist layer 214 fully covers a silicon-containing material 212. That is, the resist layer 214 covers at least substantially all of a major surface of the substrate 210 that will be the focus of subsequent processing so that the substrate 210 has a covered edge region 216 resulting in fully covered substrate 217. In this specific example, the resist layer 214 extends around the edge of the substrate 210 and terminates on the opposing side of the substrate 210, although this is but one schematic representation (the exact shape may depend on various factors such as the type of resist and the formation technique).

During the edge bead removal step 201, a resist solvent 224 is provided at the edge region of the substrate 210 to remove a portion of the resist layer 214 and expose the silicon-containing material 212 to form an exposed edge region 211. After the edge bead removal step 201, the resist layer 214 exists on the substrate 210 substantially only in a covered interior region 215. The resist material may also have been removed from the sides and backside of the substrate 210, as shown. Other cleaning processes may also be incorporated to ensure that resist material is not on the sides and backside of the substrate 210.

The resist solvent 224 may have any suitable chemical composition, and may be selected so as to selectively remove the resist layer 214 without damaging other materials of the substrate 210. Additionally, the resist solvent 224 be delivered in the liquid phase as part of a wet process (e.g., a stream of liquid directed at the edge region of a spinning substrate), but dry processes utilizing gas phase species and/or plasma species may also be used to remove the resist layer 214 in the edge region and form the exposed edge region 211.

Referring now to FIG. 2B, the process 200 includes a conversion step 203 after the edge bead removal step 201, such as after the substrate 210 is received by a processing chamber within which the conversion step 203 is performed (e.g., supported by a substrate holder). It should be noted that here and in the following a convention has been adopted for brevity and clarity wherein elements adhering to the pattern [x03] where ‘x’ is the figure number may be related implementations of a conversion step in various embodiments. For example, the conversion step 203 may be similar to the conversion step 103 except as otherwise stated. An analogous convention has also been adopted for other elements as made clear by the use of similar terms in conjunction with the aforementioned numbering system.

During the conversion step 203, the silicon-containing material 212 of the exposed edge region 211 is treated with a metal halide precursor to convert the silicon-containing material 212 into a metal-containing protective layer 220 to form a protected edge region 213. In this specific example of the conversion step 203, the metal halide precursor is provided as a metal halide precursor gas 222, which is excited as a metal halide plasma 223 during the conversion step 203.

After the conversion step 203, the etching process 200 includes a post conversion development step 204 during which the resist layer 214 is exposed to a developer 240 (which may be in the liquid phase or may be in the gas phase, plasma phase, or a combination thereof) to form a developed interior region 218. The developer 240 selectively removes portions of the resist layer 214 (e.g., features that have been modified by a lithographic exposure process, such as by structured light, or other means) to pattern the developed interior region 218 and form openings 242 that expose the silicon-containing material 212 resulting in exposed interior surfaces 241.

Turning now to FIG. 2C, the substrate 210 is exposed to a silicon etchant 244 during an etch step 205 of the etching process 200 to etch the silicon-containing material 212 of the exposed interior surfaces 241 through the openings 242 and create recesses 243 in the silicon-containing material 212 forming an etched interior region 219. In various embodiments, the etch step 205 utilizes a dry etching process, and is a plasma etching process in one embodiment. For example, as shown here, the silicon etchant 244 may be provided in the gas phase and an etchant plasma 245 may be excited from the gas.

During the etch step 205, little or no etching of the protected edge region 213 occurs due to the increased etch resistance of the metal-containing protective layer 220. Although schematically illustrated as not be etched at all, the metal-containing protective layer 220 may be etched to some extent (e.g., much slower than the silicon-containing material 212, for example). However, the metal-containing protective layer 220 is configured to provide protection during the etch step 205 so that substantially none of the silicon-containing material 212 in the edge region is etched.

Optionally, after the etch step 205, the metal-containing protective layer 220 may be removed using a metal etchant 246 (e.g., a tungsten etchant) which again uncovers the silicon-containing material 212 in the exposed edge region 211 (although now the surface may be somewhat lower, as shown, due to silicon of the silicon-containing material 212 being replaced by metal during the conversion step 203). In various embodiments, the metal-containing protective layer 220 is removed without igniting a direct plasma. For example, in one embodiment, the metal etchant 246 is in the gas phase and no plasma is ignited during the metal removal step 206. This may have the advantage of selectively removing the metal-containing protective layer 220 without damaging the interior features of the substrate 210.

Alternatively, the metal etchant 246 may include remote plasma species (i.e., species that are generated in a remote chamber and provided into the processing chamber with the substrate 210 using diffusion, for example). The remote plasma species may also have the advantage of being less damaging to structures on the substrate 210 than a direct plasma, for example.

Optionally, though it may not be considered part of the metal removal step 206, the resist layer 214 may also be removed before, after or during the metal removal step 206 exposing the interior region (which is now a patterned interior region 247), as shown. For example, the resist layer 214 may be removed using an ashing process or other suitable process. Notably, in contrast to conventional techniques, after the resist layer 214 is removed and the metal removal step 206 has been performed, structures have been formed in the patterned interior region 247 during the etch step 205 without damaging the exposed edge region 211.

FIG. 3 schematically illustrates an example process that includes a conversion step to convert exposed silicon-containing material in both an edge region and exposed interior regions of a substrate to metal-containing protective material in accordance with embodiments of the invention. The process of FIG. 3 may be a specific implementation of or include other processes described herein such as the process of FIG. 1, for example. Similarly labeled elements may be as previously described.

Referring to FIG. 3, a process 300 includes a pre-conversion lithography step 302, a conversion step 303, and a post conversion development step 304 that are performed on a substrate 310 that starts in an initial state 393 where a first resist layer 334 overlies a covered interior region 315 and leaves an exposed edge region 311 of a silicon-containing material 312 uncovered. The first resist layer 334 is then patterned using a developer 340 (e.g., exposed and developed as part of a lithographic process) to form a first developed interior region 338 with first openings 332 that leave exposed interior surfaces 341 of the substrate 310. Notably, in this specific example, the first resist layer 334 is formed and patterned before the conversion step 303.

After the first openings 332 are formed, the silicon-containing material 312 of the exposed edge region 311 and the first resist layer 334 including the exposed interior surfaces 341 are treated with a metal halide precursor gas 322, which is excited as a metal halide plasma 323 in this specific example. The exposed portions of the silicon-containing material 312 are converted to both a metal-containing protective layer 320 (forming a protected edge region 313) and also to metal-containing protective surfaces 330.

A second resist layer 314 is then formed (which is a new resist layer that may be the same or a different resist material as the first resist layer 334). The second resist layer 314 is developed (i.e., after a lithographic exposure modifying the second resist layer 314 in a desired pattern) during the post conversion development step 304 to form a second developed interior region 318 using the developer 340 (or a different developer, such as if the second resist layer 314 is a different resist material). The second developed interior region 318 includes at least second openings 342 that create exposed interior surfaces 341 for subsequent processing, such as an etching process. Additionally, third openings 333 may also be formed that substantially align with some or all of the first openings 332 and leave the metal-containing protective surfaces 330 exposed during subsequent processing.

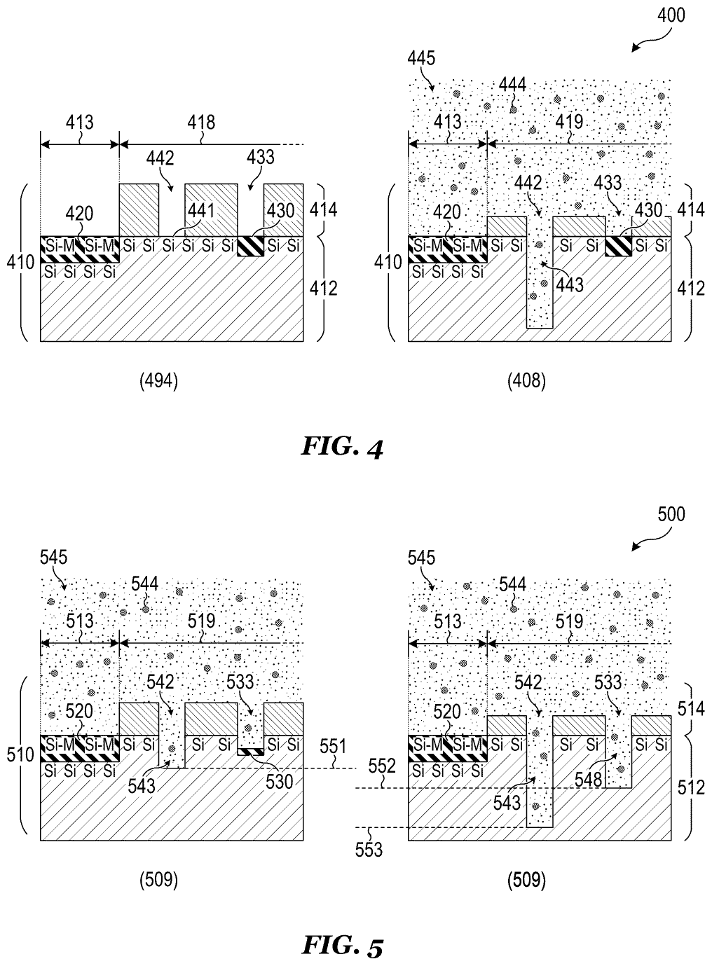

FIG. 4 schematically illustrates an example etching process that includes an etch step after a conversion step to convert exposed silicon-containing material in both an edge region and exposed interior regions of a substrate to metal-containing protective material in accordance with embodiments of the invention. The process of FIG. 4 may be a specific implementation of or include other processes described herein such as the process of FIG. 1, for example. Similarly labeled elements may be as previously described.

Referring to FIG. 4, an etching process 400 includes a selective opening step 408 (i.e., a specific example of an etch step, which may be as previously described) that is performed on a substrate 410 in an initial state 494 where a second resist layer 414 overlying a silicon-containing material 412 has been developed to form openings in a developed region and a metal-containing protective layer 420 has been formed in a protected edge region 413. The initial state 494 may represent a state after a post conversion development step (such as the post conversion development step 304 of FIG. 3, for example).

In the specific example shown here, both second openings 442 (revealing exposed interior surfaces 441) and third openings 433 (over metal-containing protective surfaces 430) have been formed in a second developed interior region 418. For example, a first developed region of a first resist layer may have previously been used to form the metal-containing protective layer 420 and used first openings to form the metal-containing protective surfaces 430 that are now exposed by the third openings 433.

During the selective opening step 408, all exposed surfaces are exposed to a silicon etchant 444 (which may be excited to form an etchant plasma 445). Specifically, the exposed surfaces include the metal-containing protective layer 420, the second resist layer 414, the silicon-containing material 412 through the second openings 442, and the metal-containing protective surfaces 430 through the third openings 433. The silicon etchant 444 etches the silicon-containing material 412 in the region of the second openings 442 while the remaining regions of the silicon-containing material 412 are protected by the metal-containing protective layer 420, the second resist layer 414, and the metal-containing protective surfaces 430, which are together used as etch masks.

After the selective opening step 408, an etched interior region 419 has been formed where the pattern of the second openings 442 has been transferred as recesses 443 into the silicon-containing material 412 at a desired etch depth. The selective opening step 408 is provided as an example where the metal-containing protective surfaces 430 are not consumed during the etch and thereby fully protect the silicon-containing material 412 in the region of the third openings 433. However, this does not have to be the case (an example of which is discussed in reference to the next figure).

FIG. 5 schematically illustrates another example etching process that includes a conversion step to convert exposed silicon-containing material in both an edge region and exposed interior regions of a substrate to metal-containing protective material in accordance with embodiments of the invention. The process of FIG. 5 may be a specific implementation of or include other processes described herein such as the process of FIG. 1, for example. Similarly labeled elements may be as previously described.

Referring to FIG. 5, an etching process 500 includes a delayed opening step 509 (i.e., a specific example of an etch step, which may be as previously described) that is performed on a substrate 510 that has a metal-containing protective layer 520 formed in a protected edge region 513 and a second resist layer 514 overlying a silicon-containing material 512 that has been developed to form openings (e.g., resulting from a post conversion development step, such as the post conversion development step 304 of FIG. 3, which may be similar to the initial state 494 of FIG. 4, for example).

As before, both second openings 542 and third openings 533 (over metal-containing protective surfaces 530) have been formed. However, in contrast to the selective opening step 408 of FIG. 4, during the delayed opening step 509, a silicon etchant 544 (which may be excited to form an etchant plasma 545) meaningfully etches the metal-containing protective surfaces 530 so that the silicon-containing material 512 in the third openings 533 is eventually etched.

Specifically, during the first part of the delayed opening step 509, the silicon-containing material 512 is etched through the second openings 542 to form first recesses 543 that extend to a first etch depth 551. At some point during the delayed opening step 509, the metal-containing protective surfaces 530 are consumed and the silicon-containing material 512 in both the second openings 542 and the third openings 533 are simultaneously etched forming second recesses 548 through the third openings 533 that extend to a second etch depth 552. Because the first recesses 543 have already been etched for some time before the second recesses 548, the first recesses 543 are extended to a third etch depth 553 that is deeper than the second etch depth 552. The relative height of the second etch depth 552 and the third etch depth 553 may be controlled by varying parameters during a conversion step, for example.

After the delayed opening step 509, an etched interior region 519 has been formed where the pattern of the second openings 542 and the pattern of the third openings 533 have both been transferred as the first recesses 543 and the second recesses 548 into the silicon-containing material 512 at the second etch depth 552 and the third etch depth 553, respectively.

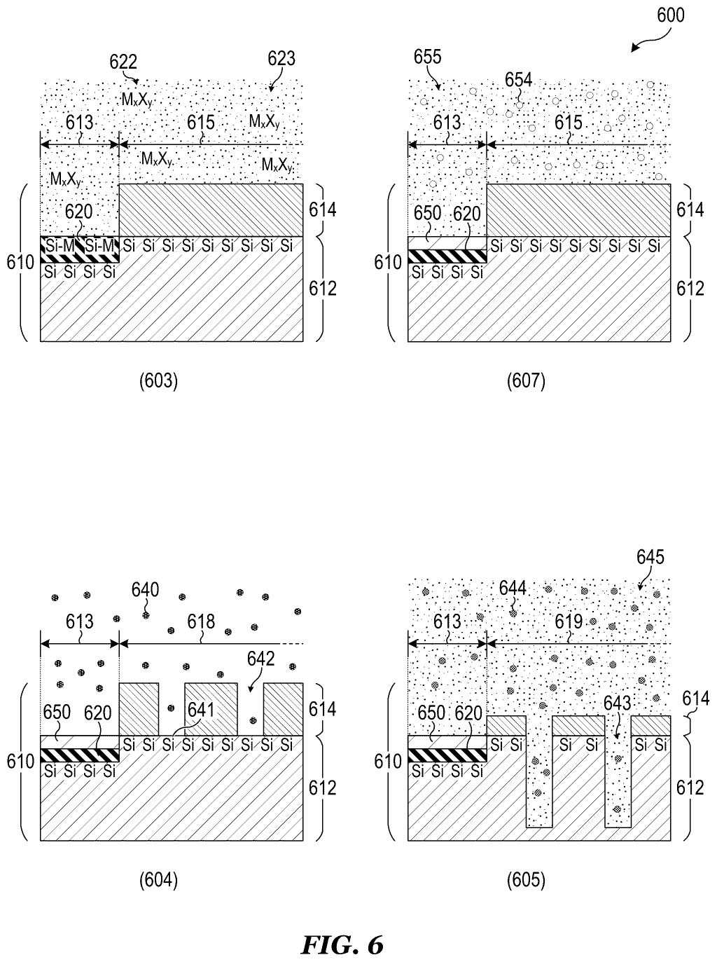

FIG. 6 schematically illustrates an example etching process that includes a conversion step to convert an edge region of a substrate to a metal-containing protective layer and an oxidation step to convert the metal-containing protective layer to a metal oxide-containing protective layer in accordance with embodiments of the invention. The process of FIG. 6 may be a specific implementation of or include other processes described herein such as the process of FIG. 1, for example. Similarly labeled elements may be as previously described.

Referring to FIG. 6, an etching process 600 includes a conversion step 603, an oxidation step 607, a post conversion development step 604, and an etch step 605 that are performed on a substrate 610 that has a resist layer 614 overlying a silicon-containing material 612 in a covered interior region 615. During the conversion step 603, the silicon-containing material 612 and the resist layer 614 are treated with a metal halide precursor gas 622 (which may be excited as a metal halide plasma 623) to form a metal-containing protective layer 620 in a protected edge region 613 of the substrate 610.

In this specific example, the oxidation step 607 is included after the conversion step 603. During the oxidation step 607, the metal-containing protective layer 620 is treated with an oxygen species 654, which may also be excited as an optional oxygen plasma 655. For example, the oxygen species 654 may be or may include oxygen plasma species excited from an oxygen-containing gas, such as diatomic oxygen O₂(g), ozone O₃(g), water vapor H₂O(g), carbon dioxide CO₂(g), carbon monoxide CO(g), and others. Alternatively, the oxygen species 654 may be solely in the gas phase or be provided from a remote plasma source.

The oxygen species 654 react with the metal-containing protective layer 620 to form a metal oxide-containing protective layer 650, which may have the benefit of providing further protection from subsequent processing, such as an etching process. For example, metal oxide bonds may be formed in and at the surface of the metal-containing protective layer 620 (e.g., M—O bonds, such as W—O bonds, Mo—O, Ti—O bonds, etc.). Although shown as only extending partially into the metal-containing protective layer 620, oxygen may fully penetrate into the metal-containing protective layer 620 in some cases.

At this stage the process could be considered complete with the silicon-containing material 612 in the edge region of the substrate 610 being protected by the metal oxide-containing protective layer 650 and the substrate 610 ready for any type of subsequent processing (similar to the process 100 of FIG. 1, for example). However, in this specific example, the post conversion development step 604 and the etch step 605 are performed after the oxidation step 607.

Both the post conversion development step 604 and the etch step 605 may be similar to analogous steps that have been previously discussed, except that in this specific example, the silicon-containing material 612 in the protected edge region 613 is further protected by the metal oxide-containing protective layer 650. That is, during the post conversion development step 604, the resist layer 614 is exposed to a developer 640 to form a developed interior region 618 that includes openings 642 revealing exposed interior surfaces 641.

Then, during the etch step 605, the substrate 610 is exposed to a silicon etchant 644 (which may be excited as an etchant plasma 645) to etch the silicon-containing material 612 of the exposed interior surfaces 641 creating recesses 643 and form an etched interior region 619. Little or no etching of the protected edge region 613 occurs while the silicon-containing material 612 is protected by the metal oxide-containing protective layer 650 (and potentially also protected by the metal-containing protective layer 620 underneath, such as in cases where the metal oxide-containing protective layer 650 is fully consumed).

FIG. 7 schematically illustrates an example system usable to perform methods and processes that include a conversion step during which an exposed silicon-containing edge region of a substrate is exposed to a metal halide precursor to convert the edge region to a metal-containing protective layer in accordance with embodiments of the invention.

Referring to FIG. 7, a processing system 700 (e.g., a vacuum system, such as a deposition system or an etching system) includes a processing system 700 configured to contain a substrate 710. The processing system 700 may be any suitable system, and is a plasma system in various embodiments. In one embodiment, the processing system 700 is a reactive-ion etching (RIE) etching system. A substrate holder 760 is disposed within the processing system 700 and configured to support the substrate 710.

A precursor source 772 (e.g., a gas source that includes a metal halide precursor) is fluidically coupled to the processing system 700 and is configured to supply a metal halide precursor gas 722 into the processing chamber 770. An optional oxygen source 774 (e.g., a gas source that includes oxygen) may also be fluidically coupled to the processing chamber 770 and may be configured to supply an oxygen-containing gas into the processing chamber 770 (e.g., for when an oxidation step is included after a conversion step to protect the edge region of the substrate 710). When the processing system 700 is an etching system, an optional etchant gas source 776 may be included, which may be used to etch interior regions of the substrate 710 in an etch step. Of course, other gases may also be provided into the processing chamber 770 such as with an optional additional gas source 778 that may be configured to supply other gases as needed, such as carrier gases, additional reactants, or others.

The processing system 700 may be configured to generate plasma during one or more steps of a process, such as a conversion step, etch step, and others. For example, an optional source power supply 764 may be configured to couple source power 765 to the processing system 700 in order to excite plasma from gases within the chamber (e.g., an optional metal halide plasma 723, as well as other plasmas, if desired). Alternatively or additionally, an optional remote plasma chamber 766 may be included that is configured to generate a remote plasma 768. The remote plasma 768 may be fluidically coupled to the processing chamber 770 (e.g., allowing plasma species to diffuse into the processing chamber 770). For example, the optional remote plasma chamber 766 may be used in addition to or instead of the precursor source 772. Remote plasma may also be used for other steps as desired, such as for a metal removal step to remove the metal-containing protective layer.

An exhaust valve 789 may be included to control evacuation of the processing system 700 during the plasma etching processes. An optional temperature monitor 786 may be included to monitor and/or aid in controlling the temperature of the substrate 710 and the environment in the processing system 700. An optional temperature control device 787 may be included to raise or lower the temperature of the substrate 710 above or below the equilibrium temperature during the plasma etching processes. Although shown as being in the substrate holder 760, the optional temperature control device 787 may also be or include a radiative heating device disposed in the processing chamber 770. An optional motor 788 may also be included to improve process uniformity for some processes.

A controller 780 may be operatively coupled to the various components of the processing system 700, including gas sources, power supplies, and valves. The controller 780 includes a processor 782 and a memory 784 (i.e., a non-transitory computer-readable medium and may be more than one memory) that stores one or more programs including instructions that, when executed by the processor 782, cause the processing system 700 to completely or partially perform the methods and processes described herein. For example, the memory 784 may have volatile memory (e.g., random access memory (RAM)) and non-volatile memory (e.g., flash memory). Alternatively, one or more of the programs may be stored in physical memory at a remote location, such as in cloud storage. The processor 782 may be any suitable processor, such as the processor of a microcontroller, a general-purpose processor (such as a central processing unit (CPU), a microprocessor, a field-programmable gate array (FPGA), an application-specific integrated circuit (ASIC), and others.

The processing system 700 is configured to perform processes (e.g., etching processes) that include a conversion step during which an exposed silicon-containing edge region of a substrate is exposed to a metal halide precursor (e.g., the metal halide precursor gas 722 that is excited as the optional metal halide plasma 723) to convert the edge region to a metal-containing protective layer. Further, the processing system 700 is configured to perform various methods that incorporate some or all steps of embodiment processes as may be apparent to those of ordinary skill in the art in view of the present disclosure. For example, the processing system 700 is configured to control gas flow rates, chamber pressure, and power levels during the conversion step and any other included steps.

Additionally, the processing system 700 may include additional processing chambers, as one or more steps of the embodiment processes may be performed in a chamber other than the processing chamber 770. For example, when the process includes one or more development steps and etch steps in addition to the conversion step, the various steps may be performed in separate chambers (e.g., steps using wet processes versus dry processes, for example). Additionally, various steps incorporating dry processes may be performed in the same chamber or in separate chambers, depending on the capabilities of the equipment and the details of a given application. Therefore, the processes described herein may advantageously have the flexibility of being performed by a variety of tools (without tool modification, in some cases), all of which may be included in the processing system 700.

FIG. 8 illustrates a flowchart of a method of protecting an edge region of a substrate that may be implemented by processes that include a conversion step during which an exposed silicon-containing edge region of a substrate is exposed to a metal halide precursor to convert the edge region to a metal-containing protective layer in accordance with embodiments of the invention. The method of FIG. 8 may be combined with other methods and performed using the systems and apparatuses as described herein. For example, the method of FIG. 8 may be combined with any of the embodiments of FIGS. 1-7. Although shown in a logical order, the arrangement and numbering of the steps of FIG. 8 are not intended to be limited. The method steps of FIG. 8 may be performed in any suitable order or concurrently with one another as may be apparent to a person of skill in the art.

Referring to FIG. 8, a method 800 of protecting an edge region of a substrate includes a conversion step 803 performed on a substrate in an initial state 893 in which the substrate has an exposed silicon-containing edge region surrounding an interior region that is covered by a resist layer is received into a processing chamber. The resist layer may be developed, exposed (i.e., using a lithographic process) and undeveloped, or may be unmodified after being formed on the substrate. In one embodiment, the exposed edge region is formed using an edge bead removal step 801 during which a portion of the resist layer is removed to expose the silicon-containing edge region of the substrate. When the resist layer includes features in the initial state 893, they may be formed using a prior step, such as in a pre-conversion lithography step 802 during which the resist layer is developed to form openings (i.e., in a desired pattern) exposing surfaces of an interior region of the substrate.

During the conversion step 803, the exposed silicon-containing material and the resist layer are both exposed with a metal halide precursor. The metal halide precursor selectively converts the silicon-containing material to a metal-containing protective material. A metal-containing protective layer is formed at least in the edge region of the substrate. When the resist layer includes openings, exposed surfaces of the interior region are also treated with the metal halide precursor resulting in the formation of metal-containing protective surface therein (shown as concurrent conversion step 892).

At this stage, the substrate may be ready for subsequent processing while the metal-containing protective material protects various regions of the silicon-containing material on the substrate. Additional treatments may also be performed to make the metal-containing material even more resistant to subsequent processes, such as an oxidation step 807. For example, the metal-containing protective material may be treated with oxygen (e.g., gas phase, plasma phase (remote or direct), or a combination thereof) during the oxidation step 807 to form metal oxide-containing protective material. After the silicon-containing material is protected during the desired subsequent processing, the metal-containing protective material may be selectively removed in a metal removal step 806 (e.g., without exciting plasma).

The subsequent processing may include an etching process, such as shown here in the example flowchart of the method 800. The resist layer may be developed in a post conversion development step 804 to form openings exposing the interior region of the substrate. The resist layer developed during the post conversion development step 804 may be the original resist layer of the conversion step 803 or a subsequent resist layer that has been formed after the conversion step 803, such as when patterning is performed in stages.

During a etch step 805, the interior region of the substrate may be etched through the openings using the developed resist layer and the metal-containing protective material as etch masks. When a subset of the openings includes metal-containing protective material, some of the interior region may be etched while other portions may be protected during the etch step 805. For example, the etch step 805 may include a selective opening step 808 during which recesses are etched through a subset of the openings of the resist layer to a first depth while the remaining openings are protected by the metal-containing protective material. In some embodiments, the etch step 805 may then stop at the first etch depth. However, in other embodiments, the etch step 805 may continue during a delayed opening step 809 where the recesses are etched through the subset of openings to a second depth while additional recesses are etched through the remaining openings to a third depth (that is of course less than the second depth).

Example embodiments of the invention are summarized here. Other embodiments can also be understood from the entirety of the specification as well as the claims filed herein.

Example 1. A method of protecting an edge region of a substrate including: receiving a substrate into a processing chamber, the substrate including an exposed silicon-containing edge region surrounding an interior region underlying a first resist layer; and treating the exposed silicon-containing edge region and the first resist layer with a metal halide precursor to selectively convert the exposed silicon-containing edge region to a metal-containing protective layer.

Example 2. The method of example 1, further including: processing the interior region while protecting edge region substrate material using the metal-containing protective layer; and selectively removing the metal-containing protective layer without exciting plasma after processing the interior region.

Example 3. The method of one of examples 1 and 2, where treating the exposed silicon-containing edge region and the first resist layer with the metal halide precursor includes exciting plasma from a metal halide precursor gas.

Example 4. The method of one of examples 1 to 3, where treating the exposed silicon-containing edge region and the first resist layer with the metal halide precursor includes heating the substrate.

Example 5. The method of one of examples 1 to 4, where the metal-containing protective layer includes a metal silicide.

Example 6. The method of one of examples 1 to 5, further including: treating the metal-containing protective layer with oxygen to form a metal oxide-containing protective layer.

Example 7. The method of one of examples 1 to 6, further including: developing the first resist layer to form openings exposing the interior region after treating the exposed silicon-containing edge region and the first resist layer with the metal halide precursor; and etching the interior region through the openings using the first resist layer and the metal-containing protective layer as etch masks.

Example 8. The method of one of examples 1 to 6, further including: developing the first resist layer to form first openings exposing first surfaces of the interior region before treating the exposed silicon-containing edge region and the first resist layer with the metal halide precursor; and treating the first surfaces of the interior region with the metal halide precursor to convert the first surfaces to metal-containing protective surfaces while treating the exposed silicon-containing edge region and the first resist layer with the metal halide precursor.

Example 9. The method of example 8, further including: etching the interior region through second openings of a second resist layer using the metal-containing protective layer, the-metal containing protective surfaces, and the second resist layer as etch masks.

Example 10. The method of example 9, where: the second resist layer includes third openings exposing one or more of the metal-containing protective surfaces; and etching the interior region includes etching recesses through the second openings to a first depth while etching the metal-containing protective surfaces through the third openings, and etching the recesses through the second openings to a second depth while etching recesses through the third openings to a third depth that is less than the second depth.

Example 11. The method of one of examples 1 to 10, where the metal halide precursor is tungsten hexafluoride (WF₆).

Example 12. A method of protecting an edge region of a substrate during an etching process, the method including: receiving a substrate into a processing chamber, the substrate including an exposed silicon-containing edge region surrounding an interior region underlying a resist layer; treating the exposed silicon-containing edge region and the resist layer with plasma excited from a tungsten halide precursor gas to selectively convert the exposed silicon-containing edge region to a tungsten-containing protective layer; developing the resist layer to form openings exposing the interior region; and etching the interior region through the openings using the resist layer and the tungsten-containing protective layer as etch masks.

Example 13. The method of example 12, further including: selectively removing the tungsten-containing protective layer without exciting plasma after etching the interior region.

Example 14. The method of one of examples 12 and 13, further including: treating the tungsten-containing protective layer with oxygen plasma to form a metal oxide-containing protective layer before developing the resist layer.

Example 15. The method of one of examples 12 to 14, where the tungsten halide precursor gas is tungsten hexafluoride (WF₆) gas, and where the tungsten-containing protective layer includes tungsten silicide (WSiₓ).

Example 16. A system including: a processing chamber; a substrate holder disposed in the processing chamber and configured to support a substrate including an exposed silicon-containing edge region surrounding an interior region underlying a resist layer; a precursor source fluidically coupled to the processing chamber and configured to provide a metal halide precursor into the processing chamber; and at least one controller operatively coupled to the precursor source, the at least one controller including one or more processors and at least one non-transitory computer-readable medium storing one or more programs including instructions that, when executed by the one or more processors, cause the system to treat the exposed silicon-containing edge region and the resist layer with the metal halide precursor to selectively convert the exposed silicon-containing edge region to a metal-containing protective layer.

Example 17. The system of example 16, further including: an oxygen source fluidically coupled to the processing chamber and operatively coupled to the at least one controller, the oxygen source being configured to provide oxygen species into the processing chamber, where the instructions further cause the system to treat the metal-containing protective layer with oxygen to form a metal oxide-containing protective layer.

Example 18. The system of one of examples 16 and 17, further including: a source power supply operatively coupled to the at least one controller and configured to couple source power to gases in the processing chamber, where the precursor source is further configured to provide the metal halide precursor as a metal halide precursor gas, and where the instructions further cause the system to excite plasma from the metal halide precursor gas to treat the exposed silicon-containing edge region and the resist layer.

Example 19. The system of one of examples 16 to 18, further including: a heater operatively coupled to the at least one controller and configured heat the substrate, where the instructions further cause the system to heat the substrate while treating the exposed silicon-containing edge region and the resist layer.

Example 20. The system of one of examples 16 to 19, where the precursor source is configured to provide tungsten hexafluoride (WF₆) gas into the processing chamber.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of protecting an edge region of a substrate comprising:
receiving a substrate into a processing chamber, the substrate comprising an exposed silicon-containing edge region surrounding an interior region underlying a first resist layer; and
treating the exposed silicon-containing edge region and the first resist layer with a metal halide precursor to selectively convert the exposed silicon-containing edge region to a metal-containing protective layer.

2. The method of claim 1, further comprising:
developing the first resist layer to form openings exposing the interior region after treating the exposed silicon-containing edge region and the first resist layer with the metal halide precursor; and
etching the interior region through the openings using the first resist layer and the metal-containing protective layer as etch masks.

3. The method of claim 1, further comprising:
processing the interior region while protecting edge region substrate material using the metal-containing protective layer; and
selectively removing the metal-containing protective layer without exciting plasma after processing the interior region.

4. The method of claim 1, wherein treating the exposed silicon-containing edge region and the first resist layer with the metal halide precursor comprises exciting plasma from a metal halide precursor gas.

5. The method of claim 1, wherein treating the exposed silicon-containing edge region and the first resist layer with the metal halide precursor comprises heating the substrate.

6. The method of claim 1, wherein the metal-containing protective layer comprises a metal silicide.

7. The method of claim 1, further comprising:
treating the metal-containing protective layer with oxygen to form a metal oxide-containing protective layer.

8. The method of claim 1, further comprising:
developing the first resist layer to form first openings exposing first surfaces of the interior region before treating the exposed silicon-containing edge region and the first resist layer with the metal halide precursor; and
treating the first surfaces of the interior region with the metal halide precursor to convert the first surfaces to metal-containing protective surfaces while treating the exposed silicon-containing edge region and the first resist layer with the metal halide precursor.

9. The method of claim 8, further comprising:
etching the interior region through second openings of a second resist layer using the metal-containing protective layer, the-metal containing protective surfaces, and the second resist layer as etch masks.

10. The method of claim 9, wherein:
the second resist layer comprises third openings exposing one or more of the metal-containing protective surfaces; and
etching the interior region comprises
etching recesses through the second openings to a first depth while etching the metal-containing protective surfaces through the third openings, and
etching the recesses through the second openings to a second depth while etching recesses through the third openings to a third depth that is less than the second depth.

11. The method of claim 1, wherein the metal halide precursor is tungsten hexafluoride (WF₆).

12. A method of protecting an edge region of a substrate during an etching process, the method comprising:
receiving a substrate into a processing chamber, the substrate comprising an exposed silicon-containing edge region surrounding an interior region underlying a resist layer;
treating the exposed silicon-containing edge region and the resist layer with plasma excited from a tungsten halide precursor gas to selectively convert the exposed silicon-containing edge region to a tungsten-containing protective layer;
developing the resist layer to form openings exposing the interior region; and
etching the interior region through the openings using the resist layer and the tungsten-containing protective layer as etch masks.

13. The method of claim 12, further comprising:
selectively removing the tungsten-containing protective layer without exciting plasma after etching the interior region.

14. The method of claim 12, further comprising:
treating the tungsten-containing protective layer with oxygen plasma to form a metal oxide-containing protective layer before developing the resist layer.

15. The method of claim 12, wherein the tungsten halide precursor gas is tungsten hexafluoride (WF₆) gas, and wherein the tungsten-containing protective layer comprises tungsten silicide (WSiₓ).

16. A system comprising:
a processing chamber;
a substrate holder disposed in the processing chamber and configured to support a substrate comprising an exposed silicon-containing edge region surrounding an interior region underlying a resist layer;
a precursor source fluidically coupled to the processing chamber and configured to provide a metal halide precursor into the processing chamber; and
at least one controller operatively coupled to the precursor source, the at least one controller comprising one or more processors and at least one non-transitory computer-readable medium storing one or more programs including instructions that, when executed by the one or more processors, cause the system to treat the exposed silicon-containing edge region and the resist layer with the metal halide precursor to selectively convert the exposed silicon-containing edge region to a metal-containing protective layer.

17. The system of claim 16, further comprising:
an oxygen source fluidically coupled to the processing chamber and operatively coupled to the at least one controller, the oxygen source being configured to provide oxygen species into the processing chamber,
wherein the instructions further cause the system to treat the metal-containing protective layer with oxygen to form a metal oxide-containing protective layer.

18. The system of claim 16, further comprising:
a source power supply operatively coupled to the at least one controller and configured to couple source power to gases in the processing chamber,
wherein the precursor source is further configured to provide the metal halide precursor as a metal halide precursor gas, and wherein the instructions further cause the system to excite plasma from the metal halide precursor gas to treat the exposed silicon-containing edge region and the resist layer.

19. The system of claim 16, further comprising:
a heater operatively coupled to the at least one controller and configured heat the substrate,
wherein the instructions further cause the system to heat the substrate while treating the exposed silicon-containing edge region and the resist layer.

20. The system of claim 16, wherein the precursor source is configured to provide tungsten hexafluoride (WF₆) gas into the processing chamber.
